(19) United States
(12) Patent Application Publication
(10) Pub. No.: US 2025/0366296 A1
(43) Pub. Date: Nov. 27, 2025

(54) DISPLAY DEVICE USING LIGHT-EMITTING ELEMENT AND MANUFACTURING METHOD THEREFOR

(71) Applicant: LG ELECTRONICS INC., Seoul (KR)

(72) Inventors: Hwanjoon CHOI, Seoul (KR); Byungjoon RHEE, Seoul (KR); Eunjeong KANG, Seoul (KR)

(73) Assignee: LG ELECTRONICS INC., Seoul (KR)

(21) Appl. No.: 18/869,650

(22) PCT Filed: Jun. 13, 2022
(86) PCT No.: PCT/KR2022/008285

§ 371 Date: Nov. 26, 2024

(51) Int. Cl. H10H 29/85; H01L 25/075; H10H 29/80

(52) U.S. Cl. CPC H10H 29/857; H01L 25/0753; H10H 29/8321

(57) ABSTRACT

The present disclosure can be applied to technical fields relating to display devices, and relates to a display device using, for example, a micro light-emitting diode (LED) and a manufacturing method therefor. The present disclosure, which is a display device using a semiconductor light-emitting element, may comprise: a wiring substrate; first electrodes defining unit sub-pixel regions and arranged on the wiring substrate; light-emitting elements having first type electrodes disposed on the first electrodes; a plurality of conductive balls electrically connecting the first type electrodes of the light-emitting elements with the first electrodes; and conductive adhesive parts located on the conductive balls to fix the conductive balls to the first electrodes and/or to the first type electrodes.

### TECHNICAL FIELD

The present disclosure relates to a technical field related to a display device, for example, a display device using a micro light emitting diode (LED) and a manufacturing method thereof.

### BACKGROUND ART

Recently, in a field of a display technology, display devices having excellent characteristics such as thinness, flexibility, and the like are developed. On the other hand, currently commercialized major displays are represented by LCDs (liquid crystal displays) and OLEDs (organic light emitting diodes).

However, in the case of LCDs, there are problems, such as a non-fast response time and difficulty in implementing flexibility, and in the case of OLEDs, there are problems, such as a short lifespan and poor mass production yield.

On the other hand, light emitting diodes (LEDs) are semiconductor light emitting elements well known as converting current into light, and starting with commercialization of red LEDs using GaAsP compound semiconductors in 1962, they are used as light sources for display images in electronic devices including information and communication devices along with GaP:N-based green LEDs. Therefore, a solution to solve the above-described problems may be proposed by implementing displays using semiconductor light emitting elements. The semiconductor light emitting elements have various advantages, such as a long lifespan, low power consumption, excellent initial driving characteristics, and high vibration resistance, compared to filament-based light emitting elements.

The size of these semiconductor light emitting elements has recently been reduced to several tens of micrometers. Therefore, if a display device is implemented using these small-scale sized semiconductor light emitting elements, a very large number of semiconductor light emitting elements must be assembled on a wiring substrate of the display device.

However, in a process of assembling these light emitting elements, there is a problem in that it is very difficult to precisely locate a large number of semiconductor light emitting elements at desired positions of the wiring substrate. This problem is becoming more severe as high-resolution displays become more common.

In this assembly process, the light emitting elements may be directly transferred to wiring electrodes or transferred using a donor substrate. At this time, conductive balls or a conductive film may be used between the electrodes of the light emitting elements and the wiring electrodes.

A problem in bonding using a conductive film (ACF) including conductive balls is that there is a probability of electrical connection of small element pads due to randomness of conductive ball positions.

When bonding using a polymer resin forming an adhesive that exists as a surface, pressure required for bonding is high due to the flow and resistance of the resin depending on a contact area.

In the case of Dexerials Corporation, which is a representative Japanese ACF company, development of display bonding using an ACF is aimed at solving the above problem by developing a thin ACF including conductive balls, the positions of which are fixed. However, this solution causes difficulty in manufacturing and incurs high costs upon application to large-area displays, thereby resulting in a large burden of material costs.

To improve a bonding margin, a partial resin coating method through a conductive paste (ACP) (pattern formation through a printing method by mixing conductive balls with a liquid) is being attempted to solve the problem.

With this solution, a degree of freedom of bonding using the ACP is higher than a degree of freedom of bonding using the ACF, but there is a problem that the ACP is not applicable to small elements due to the randomness of the positions of the conductive balls.

Meanwhile, a method of selectively forming a pattern of conductive balls on the N and P electrodes of light emitting elements on a chip on wafer (COW) has been developed, and a method of utilizing a non-conductive paste (NCP) as a bonding fixing material (adhesive part) is being used.

However, this thermal bonding has a limited bondable area due to the flatness and pressure of a bonding head.

In addition, excessive pressure or weak pressure may be applied to a specific area depending on the flatness and horizontality of the bonding head.

When bonding using conductive balls, in a local area where weak bonding pressure is applied, contact by the conductive ball may be released due to a spring back phenomenon in which the conductive ball is returned to the original position thereof at the moment when the pressure is released after bonding.

On the other hand, if excessive pressure is applied, the conductive balls have a Pac-man shape to lose restoring force, and thereby, the restoring force may not occur and thus contact may be released.

Meanwhile, when connecting an electrode of a light emitting element and a wiring electrode, a reflow electrical connection method using heat treatment is used. However, as a display area increases, electrical connection between an individual micro-LED and a wiring substrate through thermal bonding is not easy due to problems in implementing bonding equipment (an increase in pressure proportional to the flatness and area of a head).

For example, there is a problem that it is difficult to apply a method of printing a solder to an electrode pad pattern of a micro-LED with a small size of 10 μm.

When manufacturing the solder using electroplating or a deposition method, there are difficulties in electrical connection of micro-LEDs due to cost issues and limitations of surface materials for resolving surface wettability

That is, during the solder reflow heat treatment process, spread of the solder may cause electrical shorts between the N and P electrode pads of the light emitting element.

Accordingly, a solution that can solve these problems is required.

### DISCLOSURE

### Technical Task

One technical task to be solved by the present disclosure is to provide a display device using light emitting elements that may achieve electrical connection between the light emitting elements having a micro-scale size or millimeter-scale size and wiring electrodes under relaxed bonding conditions, and a manufacturing method thereof.

In addition, another technical task to be solved by the present disclosure is to provide a display device using light emitting elements that may achieve bonding between the light emitting elements and wiring electrodes with a relatively weak pressure, and a manufacturing method thereof.

In addition, yet another technical task to be solved by the present disclosure is to provide a display device using light emitting elements that may improve productivity by reducing bonding pressure required between the light emitting elements and wiring electrodes to manufacture a large-area display, and a manufacturing method thereof.

### Technical Solutions

In order to solve the above technical tasks, a first aspect of the present disclosure provides a display device using semiconductor light emitting elements including a wiring substrate, first electrodes configured to define unit subpixel areas and arranged on the wiring substrate, light emitting elements having first-type electrodes disposed on the first electrodes, a plurality of conductive balls configured to electrically connect the first-type electrodes of the light emitting elements to the first electrodes, and conductive adhesives parts located on the conductive balls to fix the conductive balls to at least one of the first electrodes or the first-type electrodes.

As an exemplary embodiment, the conductive adhesive parts may include conductive nanoparticles.

As an exemplary embodiment, the conductive adhesive parts may include a photoresist or a paste.

As an exemplary embodiment, the conductive adhesive parts may include a non-conductive paste including conductive nanoparticles.

As an exemplary embodiment, the conductive adhesive parts may be locally located on the first-type electrodes.

As an exemplary embodiment, the light emitting elements may be electrically connected to the first electrodes by the conductive balls and the conductive nanoparticles.

As an exemplary embodiment, the conductive adhesive parts may have the same width as at least one of the first electrodes or the first-type electrodes.

As an exemplary embodiment, the conductive adhesive parts may include first adhesive parts located on the first-type electrodes, and second adhesive parts located on the first electrodes.

As an exemplary embodiment, the first adhesive parts and the second adhesive parts may be in contact with each other.

As an exemplary embodiment, the first adhesive parts and the second parts may be spaced apart from each other, and be electrically connected by the conductive balls.

In order to solve the above technical tasks, a second aspect of the present disclosure provides a display device using semiconductor light emitting elements including a wiring substrate, first electrodes configured to define unit subpixel areas and arranged on the wiring substrate, light emitting elements having first-type electrodes disposed on the first electrodes, a plurality of conductive balls configured to electrically connect the first-type electrodes of the light emitting elements to the first electrodes, and adhesive parts located on the conductive balls to fix the conductive balls to at least one of the first electrodes or the first-type electrodes, wherein the adhesive parts include conductive nanoparticles.

As an exemplary embodiment, the adhesive parts may include a photoresist or a paste.

As an exemplary embodiment, the adhesive parts may be locally located on the first-type electrodes.

### Advantageous Effects

According to one embodiment of the present disclosure, the following effects are provided.

First, according to the embodiment of the present disclosure, an electrical contact area between conductive nanoparticles and conductive microparticles (conductive balls) may be increased and excessive pressing may be prevented, thereby being capable of achieving electrical connection between light emitting elements having a micro-scale size or millimeter-scale size and wiring electrodes under relaxed bonding conditions.

According to the embodiment of the present disclosure, if a pattern of the conductive nanoparticles is utilized, pressing of the conductive balls is not necessarily required. That is, normal electrical connection between the light emitting elements and the wiring electrodes is possible without applying pressure to the conductive balls. Therefore, according to the embodiment of the present disclosure, a bonding margin may be the total thickness of an adhesive layer and the conductive balls.

Therefore, if pressing of the conductive balls is not required, bonding by a relatively weak pressure may be possible, and thereby bonding pressure required for large-area bonding may be reduced.

Furthermore, according to other embodiments of the present disclosure, additional technical effects not mentioned herein may be provided. Those skilled in the art may understood these effects through the following description and drawings.

### DESCRIPTION OF DRAWINGS

FIG. 1 is a cross-sectional view showing unit pixels of a display device using semiconductor light emitting elements according to one embodiment of the present disclosure.

FIG. 2 is a cross-sectional view showing one embodiment of a subpixel within the unit pixel.

FIG. 3 is a cross-sectional view showing another embodiment of the subpixel within the unit pixel.

FIG. 4 is an enlarged view of portion A of FIG. 3.

FIG. 5 is a photograph of a comparative example, showing a state in which electrical disconnection occurs due to a cured adhesive.

FIG. 6 is a photograph of another comparative example, showing a state in which a short circuit occurs when a reflow process is used.

FIG. 7 is a flowchart showing a method of manufacturing the display device using the semiconductor light emitting elements according to one embodiment of the present disclosure.

FIGS. 8 to 21 are schematic cross-sectional views showing each operation in the method of manufacturing the display device using the semiconductor light emitting elements according to one embodiment of the present disclosure.

### BEST MODE FOR DISCLOSURE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two drawings are also within the scope of the present disclosure.

In addition, when an element such as a layer, region or module is described as being “on” another element, it is to be understood that the element may be directly on the other element or there may be an intermediate element therebetween.

Semiconductor light emitting elements described herein conceptually include LEDs, micro-LEDs, etc., and such terms may be used interchangeably.

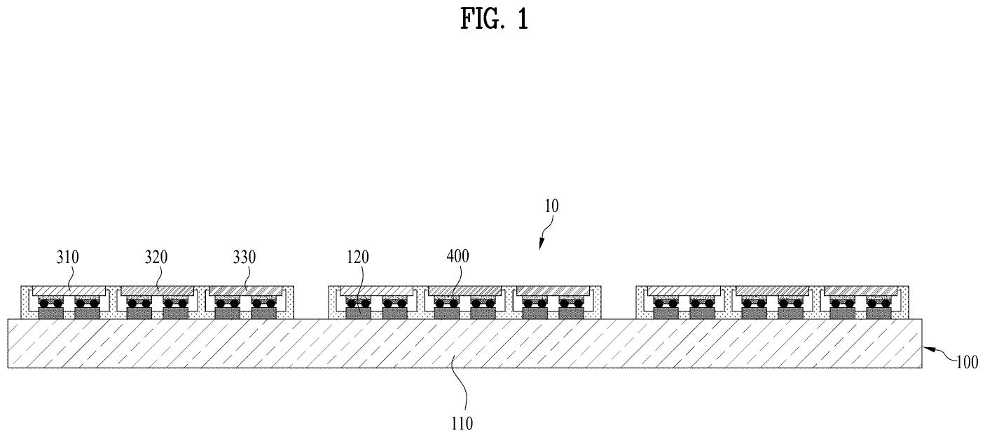

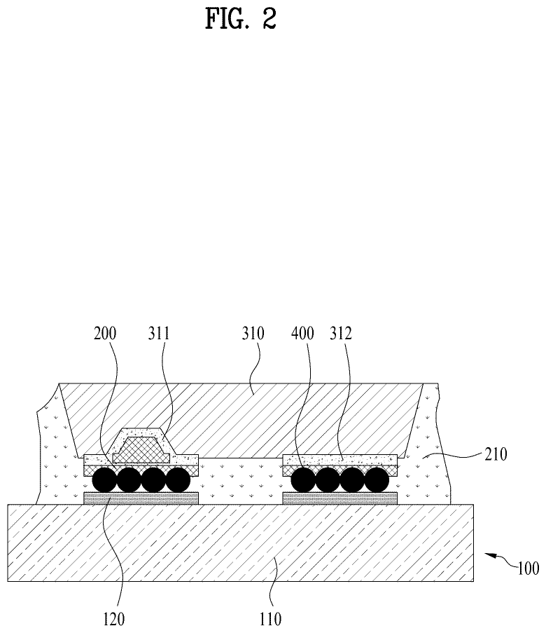

FIG. 1 is a cross-sectional view showing unit pixels of a display device using semiconductor light emitting elements according to one embodiment of the present disclosure, and FIG. 2 is a cross-sectional view showing one embodiment of a subpixel within the unit pixel.

FIG. 1 shows a display device 10 in which light emitting elements 310, 320, and 330 forming unit pixels are installed on a wiring substrate 100.

The wiring substrate 100 may have a plurality of first electrodes (wiring electrodes) 120 located on a substrate 110 to be separated from each other. Here, the wiring electrodes 120 may include data electrodes (pixel electrodes) and scan electrodes (common electrodes).

Here, three light emitting elements 310, 320, and 330 may form a unit pixel. These unit pixels may be repeatedly provided on the wiring substrate 100. Here, one light emitting element may form a unit subpixel. FIG. 1 illustrates a state in which the light emitting elements 310, 320, and 330 are installed by flip-chip bonding.

At this time, electrodes 311 and 312 (see FIG. 2) of the light emitting elements 310, 320, and 330 may be electrically connected to the wiring electrodes 120 by conductive balls 400. Here, the conductive balls 400 may have a micrometer-scale size. Therefore, the conductive balls 400 may also be called micro-conductive particles.

Although not shown, the first electrodes 120 arranged on the wiring substrate 100 may be connected to a TFT layer provided with thin film transistors (TFTs). The data electrodes (pixel electrodes) may be connected to the TFT layer. A detailed description thereof will be omitted.

Referring to FIG. 2, a first light emitting element 310 may form a horizontal structure. For example, a first-type electrode (for example, an n-type electrode) 311 and a second-type electrode (for example, a p-type electrode) 312 may be located on the same surface of the first light emitting element 310. However, the embodiment of the present disclosure may be applied identically even if the light emitting element 310 forms a vertical structure.

Here, the first light emitting element 310 may be a blue light emitting element. Hereinafter, a case in which the first light emitting element 310 is a blue light emitting element will be described as an example.

As describe above, the first-type electrode 311 may be electrically connected to the wiring electrode 120 by the conductive balls 400.

At this time, a conductive adhesive part 200 that fixes the conductive balls 400 to at least one of the first electrode (wiring electrode) 120 or the first-type electrode 311 may be located on the conductive balls 400.

In addition, the second-type electrode 312 of the light emitting element 310 may also be electrically connected to the wiring electrode 120 by the conductive balls 400.

In the same manner, the conductive adhesive part 200 that fixes the conductive balls 400 to at least one of the first electrode (wiring electrode) 120 or the second-type electrode 312 may be located on the conductive balls 400.

As an exemplary embodiment, the conductive adhesive part 200 may be locally located on the first-type electrode 311. For example, the conductive adhesive part 200 on the first-type electrode 311 and the conductive adhesive part 200 on the second-type electrode 312 may be spaced apart from each other. That is, the conductive adhesive part 200 on the first-type electrode 311 and the conductive adhesive part 200 on the second-type electrode 312 may not be connected, but may be separated from each other.

Referring to FIG. 2, the conductive adhesive parts 200 may have substantially the same width as the first-type electrode 311 and the second-type electrode 312, or the wiring electrodes 120. Here, substantially the same width may mean a case in which it can be said to be the same considering a process margin or a process error.

As an exemplary embodiment, the conductive adhesive parts 200 may include conductive nanoparticles. For example, the conductive adhesive parts 200 may include a photoresist or a paste.

The conductive adhesive parts 200 may be in a state in which conductive nanoparticles are included in a non-conductive paste (NCP), such as the photoresist or the paste, or an adhesive layer. For example, the conductive adhesive parts 200 may include a non-conductive paste including conductive nanoparticles (CNPs).

The conductive nanoparticles may be conductive particles having a nanometer-scale size. When these conductive nanoparticles are dispersed and distributed in the non-conductive paste, the non-conductive paste may have conductivity as a whole. In addition, the non-conductive paste including the conductive nanoparticles may be dried and cured to have conductivity.

In this way, the conductive balls 400 may be fixed onto the wiring electrode 120 by the adhesive part 200, or may be fixed onto the wiring electrode 120 by a separate layer, such as a paste or a photoresist.

The conductive adhesive part 200 may be an anisotropic conductive film (ACF), an anisotropic conductive paste, a solution including conductive particles, or the like. The conductive adhesive part 200 may be configured as a layer that allows electrical interconnection in the Z direction perpendicular to the thickness direction thereof, but has electrical insulation in the horizontal X-Y direction. Therefore, the conductive adhesive layer may be referred to as a Z-axis conductive layer.

The ACF is a film in which an anisotropic conductive medium is mixed with an insulating base member. When the ACF is subjected to heat and pressure, only a specific portion thereof becomes conductive by the anisotropic conductive medium. Hereinafter, it will be described that heat and pressure are applied to the ACF. However, another method may be used to make the ACF partially conductive. The other method may be, for example, application of only one of the heat and pressure or UV curing.

In addition, the anisotropic conductive medium may be, for example, conductive balls or conductive particles. For example, the ACF may be a film in which conductive balls are mixed with an insulating base member. Thus, when heat and pressure are applied to the ACF, only a specific portion of the ACF is allowed to be conductive by the conductive balls. The ACF may contain a plurality of particles formed by coating the core of a conductive material with an insulating film made of a polymer material. In this case, as the insulating film is destroyed in a portion to which heat and pressure are applied, the portion is made to be conductive by the core. At this time, the cores may be deformed to form layers that contact each other in the thickness direction of the film. As a more specific example, heat and pressure are applied to the whole ACF, and an electrical connection in the Z-axis direction is partially formed by the height difference of a counterpart adhered by the ACF.

As another example, the ACF may contain a plurality of particles formed by coating an insulating core with a conductive material. In this case, as the conductive material is deformed (pressed) in a portion to which heat and pressure are applied, the portion is made to be conductive in the thickness direction of the film. As another example, the conductive material may be disposed through the insulating base member in the Z-axis direction to provide conductivity in the thickness direction of the film. In this case, the conductive material may have a pointed end.

The ACF may be a fixed array ACF in which conductive balls are inserted into one surface of the insulating base member. More specifically, the insulating base member may be formed of an adhesive material, and the conductive balls may be intensively disposed on the bottom portion of the insulating base member. Thus, when the base member is subjected to heat and pressure, it may be deformed together with the conductive balls, exhibiting conductivity in the vertical direction.

However, the present disclosure is not necessarily limited thereto, and the ACF may be formed by randomly mixing conductive balls in the insulating base member, or may be composed of a plurality of layers with conductive balls arranged on one of the layers (as a double-ACF).

According to one embodiment of the present disclosure, a material for the conductive nanoparticles may include at least one of a metal material (Sn, In, Pb, Bi, Cu, Ag, Al, AuSn, SnBi, ITO, or the like) or a conductive polymer material (PEDOT:PSS) having a size of 100 nm or less.

The wiring electrode 120 and the first-type electrode 311 or the second-type electrode 312 may be electrically connected with a designated bonding thickness (bonding margin) by the conductive nanoparticles and the conductive balls 400, which are the conductive microparticles.

At this time, the light emitting element 310 may be electrically connected to the wiring electrodes 120 by the conductive balls 400 and the conductive nanoparticles included in the conductive adhesive part 200. That is, in this embodiment, the first-type electrode 311 and the second-type electrode 312 of the light emitting element 310 may be electrically connected to the conductive adhesive parts 200, the conductive adhesive parts 200 may be electrically connected to the conductive balls 400, and the conductive balls 400 may be electrically connected to the wiring electrodes 120.

A cap layer 210 may be located at connection portions between the light emitting element 310 and the wiring electrodes 120. The cap layer 210 may act as a bonding fixing material (an adhesive part) that fixes the connection state between the light emitting element 310 and the wiring electrodes 120. The cap layer 210 may be formed to surround the connection portion between the first-type electrode 311 and the wiring electrode 120 and the connection portion between the second-type electrode 312 and the wiring electrode 120.

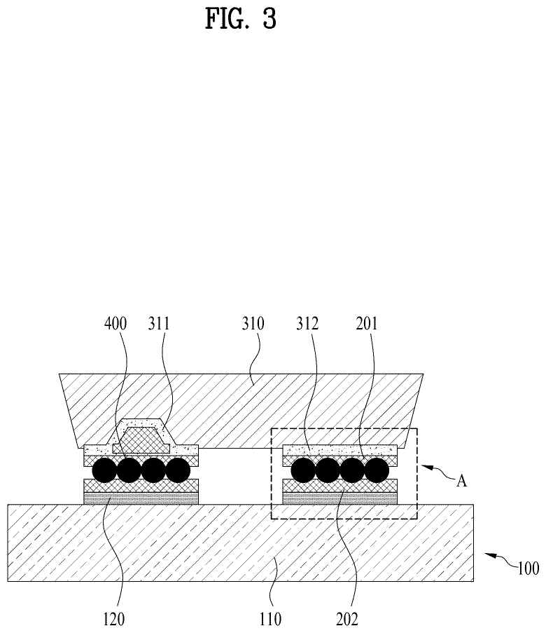

FIG. 3 is a cross-sectional view showing another embodiment of the subpixel within the unit pixel.

As described above, the first-type electrode 311 may be electrically connected to the wiring electrode 120 by the conductive balls 400.

Referring to FIG. 3, conductive adhesive parts 201 and 202 that fix the conductive balls 400 to the first electrode (wiring electrode) 120 and the first-type electrode 311 may be located on both sides of the conductive balls 400.

That is, the conductive adhesive parts 201 and 202 may include a first adhesive part 201 located on the first-type electrode 311 and a second adhesive part 202 located on the first electrode 120.

In addition, the second-type electrode 312 of the light emitting element 310 may also be electrically connected to the wiring electrode 120 by the conductive balls 400.

In the same manner, the conductive adhesive parts 201 and 202 that fix the conductive balls 400 to at least one of the first electrode (wiring electrode) 120 or the second-type electrode 312 may be located on both sides of the conductive balls 400.

At this time, the light emitting element 310 may be electrically connected to the wiring electrodes 120 by the conductive balls 400 and conductive nanoparticles included in the conductive adhesive parts 200. That is, in this embodiment, the first-type electrode 311 and the second-type electrode 312 of the light emitting element 310 may be electrically connected to the first adhesive parts 201, and the wiring electrodes 120 may be electrically connected to the second adhesive parts 202. Here, the conductive balls 400 may be located between the first adhesive part 201 and the second adhesive part 202 to be electrically connected thereto.

Although not illustrated in FIG. 3, the cap layer 210 may be located at connection portions between the light emitting element 310 and the wiring electrodes 120. That is, the cap layer 210 may act as a bonding fixing material (an adhesive part) that fixes the connection state between the light emitting element 310 and the wiring electrodes 120. The cap layer 210 may be formed to surround the connection portion between the first-type electrode 311 and the wiring electrode 120 and the connection portion between the second-type electrode 312 and the wiring electrode 120.

Matters described above with reference to FIG. 2 may be applied identically to other parts not described. Therefore, redundant description will be omitted.

According to this embodiment of the present disclosure, an electrical contact area between the conductive nanoparticles and the conductive microparticles (the conductive balls) 400 may be increased and excessive pressing may be prevented, thereby being capable of achieving electrical connection between the light emitting element 310 having a micro-scale size or millimeter-scale size and the wiring electrodes 120 under relaxed bonding conditions.

At this time, an area occupied by the conductive microparticles, such as the conductive balls 400, may be the same as an area occupied by the conductive nanoparticles.

Meanwhile, for the purpose of improving luminous efficacy or color gamut, an NCP material including particles, such as TiO₂, in a non-conductive paste (NCP) may be used as the fixing material (the adhesive part).

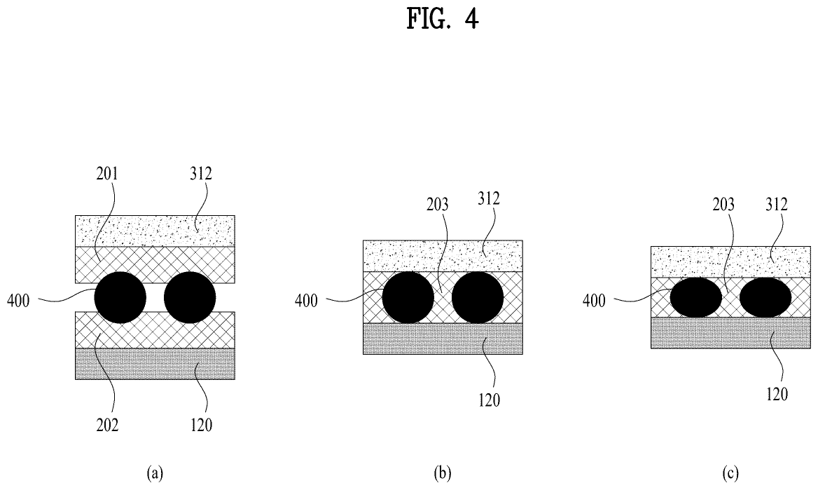

FIG. 4 is an enlarged view of portion A of FIG. 3.

Referring to FIG. 4, the conductive adhesive parts 201 and 202 may include the first adhesive part 201 located on the first-type electrode 311 and/or the second-type electrode 312 and the second adhesive part 202 located on the wiring electrode 120. In addition, the conductive balls 400 may be electrically connected between the first adhesive part 201 and the second adhesive part 202.

Referring to FIG. 4(A), the first adhesive part 201 and the second adhesive part 202 may be located to be spaced apart from each other, and the conductive balls 400 may be electrically connected between the first adhesive part 201 and the second adhesive part 202.

Referring to FIG. 4(B), the first adhesive part 201 and the second adhesive part 202 may contact each other to form one adhesive part 203. At this time, the adhesive part 203 may be located to surround the conductive balls 400.

Referring to FIG. 4(C), in the same manner as the case of FIG. 4(B), the first adhesive part 201 and the second adhesive part 202 may contact each other to form one adhesive part 203. At this time, pressure may be applied to the conductive balls 400 so that the conductive balls 400 may be deformed into an oval shape.

In general, the conductive balls 400 may electrically connect two conductors by applying pressure between the two conductors. In this embodiment, the first-type electrode 311 and/or the second-type electrode 312 and the wiring electrodes 120 may be electrically connected by the conductive balls 400, and pressure may be applied to the conductive balls 400.

A physical bonding margin by the conductive balls 40 is approximately half the diameter of the conductive balls 400. That is, electrical characteristics may be maintained until the diameter of the conductive balls 400 in the electrical connection direction is reduced by about half due to pressure, but if excessive pressure is applied to the conductive balls 400 beyond that, the electrical characteristics may be reduced.

Therefore, if conductive balls 400 having a diameter of 3 μm are used, a bonding margin of about 1.5 μm occurs.

However, if a pattern of the conductive nanoparticles according to the embodiment of the present disclosure is used, as described above, pressing of the conductive balls 400 is not necessarily required. That is, even in the cases of FIGS. 4(A) and 4(B), normal electrical connection between the first-type electrode 311 and/or the second-type electrode 312 and the wiring electrodes 120 is possible. Therefore, according to the embodiment of the present disclosure, the bonding margin may be the sum of the thicknesses of adhesive layers 201, 202, and 203 and the thickness of the conductive balls 400.

Therefore, if pressing of the conductive balls 400 is not required, bonding by a relatively weak pressure may be possible, and accordingly, a bonding pressure required for large-area bonding may be reduced.

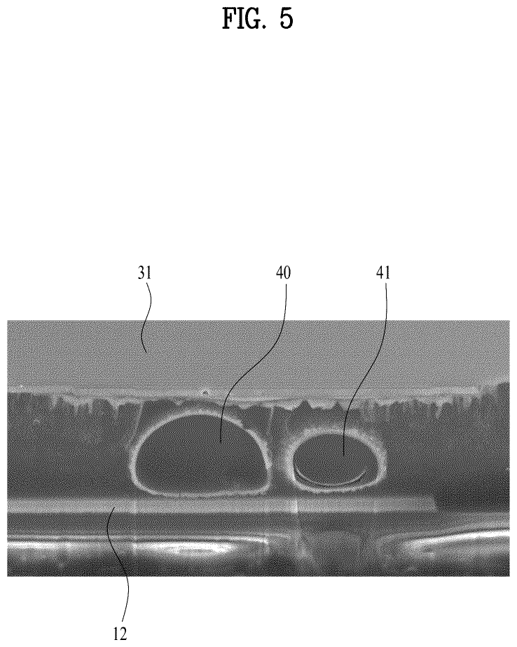

FIG. 5 is a photograph of a comparative example, showing a state in which electrical disconnection occurs due to a cured adhesive.

FIG. 5 shows an example in which conductive balls 40 and 41 are applied between a first-type electrode 31 and a wiring electrode 12 but the first-type electrode 31 and the wiring electrode 12 are not electrically connected after an adhesive surrounding the conductive balls 40 and 41 is cured.

A problem in bonding using a conductive film (ACF) including the conductive balls 40 is that there is a probability of electrical connection of a small element pad (the first-type electrode 31) due to randomness of conductive ball positions.

When bonding using a polymer resin forming an adhesive that exists as a surface, pressure required for bonding is high due to the flow and resistance of the resin depending on a contact area.

In the case of Dexerials Corporation, which is a representative Japanese ACF company, development of display bonding using an ACF is aimed at solving the above problem by developing a thin ACF including conductive balls, the positions of which are fixed. However, this solution causes difficulty in manufacturing and incurs high costs upon application to large-area displays, thereby resulting in a large burden of material costs.

To improve a bonding margin, a partial resin coating method through a conductive paste (ACP) (pattern formation through a printing method by mixing conductive balls with a liquid) is being attempted to solve the problem.

With this solution, a degree of freedom of bonding using the ACP is higher than a degree of freedom of bonding using the ACF, but the ACP may not be applied to small elements due to the randomness of the positions of the conductive balls.

Meanwhile, a method of selectively forming a pattern of conductive balls on the N and P electrodes of a light emitting element on a chip on wafer (COW) has been developed, and a method of utilizing a non-conductive paste (NCP) as a bonding fixing material (adhesive) is being used.

However, this thermal bonding has a limited bondable area due to the flatness and pressure of a bonding head.

In addition, excessive pressure or weak pressure may be applied to a specific area depending on the flatness and horizontality of the bonding head.

When bonding using conductive balls, in a local area where weak bonding pressure is applied, contact by the conductive ball may be released due to a spring back phenomenon in which the conductive ball is returned to the original position thereof at the moment when the pressure is released after bonding.

On the other hand, if excessive pressure is applied, the conductive balls have a Pac-man shape to lose restoring force, and thereby, the restoring force may not occur and thus contact may be released.

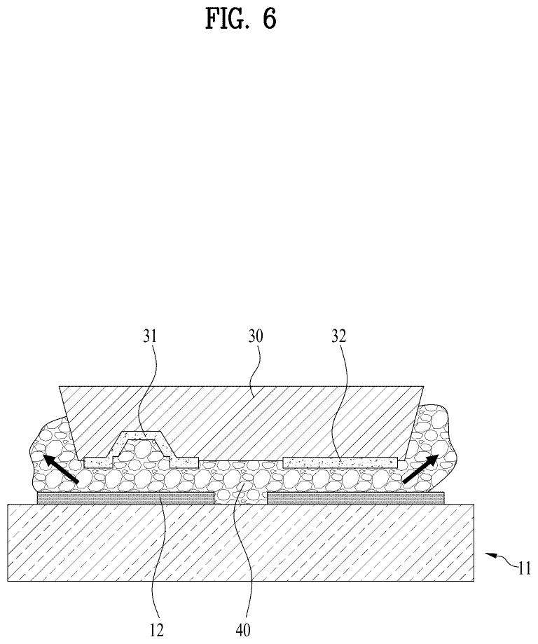

FIG. 6 is a photograph of another comparative example, showing a state in which a short circuit occurs when a reflow process is used.

A reflow electrical connection method using heat treatment has been used conventionally. However, as a display area increases, electrical connection between an individual micro-LED 30 and a wiring substrate 11 through thermal bonding is not easy due to problems in implementing bonding equipment (an increase in pressure proportional to the flatness and area of a head).

For example, there is a problem that it is difficult to apply a method of printing a solder to a pattern of electrode pads 31 and 32 of the micro-LED 30 with a small size of 10 μm.

There are difficulties in electrical connection of micro-LEDs due to cost issues and limitations of surface materials for resolving surface wettability when manufacturing the solder using electroplating or a deposition method.

That is, as shown in FIG. 6, an electrical short problem may occur between the N and P electrode pads 31 and 32 due to spread of the solder 40 during the reflow heat treatment process of the solder 40.

However, when utilizing the pattern of the conductive nanoparticles according to the embodiment of the present disclosure, as described above, since pressing of the conducive balls 400 is not necessarily required, normal electrical connection between the first-type electrode 311 and/or the second-type electrode 312 and the wiring electrodes 120 is possible even if the conductive balls 400 are not deformed.

Therefore, according to the embodiment of the present disclosure, the bonding margin is the sum of the thicknesses of the adhesive layers 201, 202, 203 and the thickness of the conductive balls 400. As such, when pressing of the conductive balls 400 is not required, bonding by a relatively weak pressure may be possible, and accordingly, bonding pressure required for large-area bonding may be reduced.

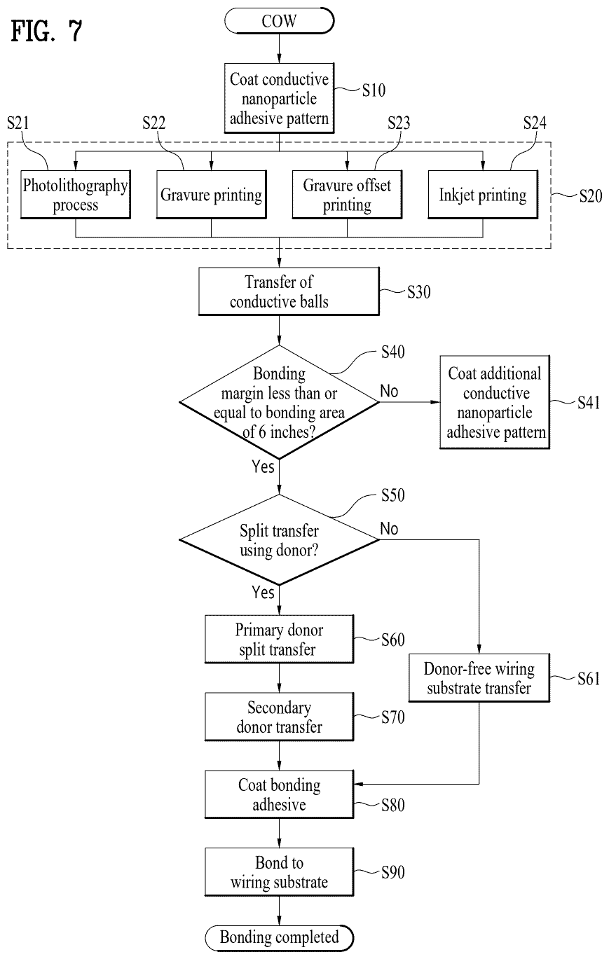

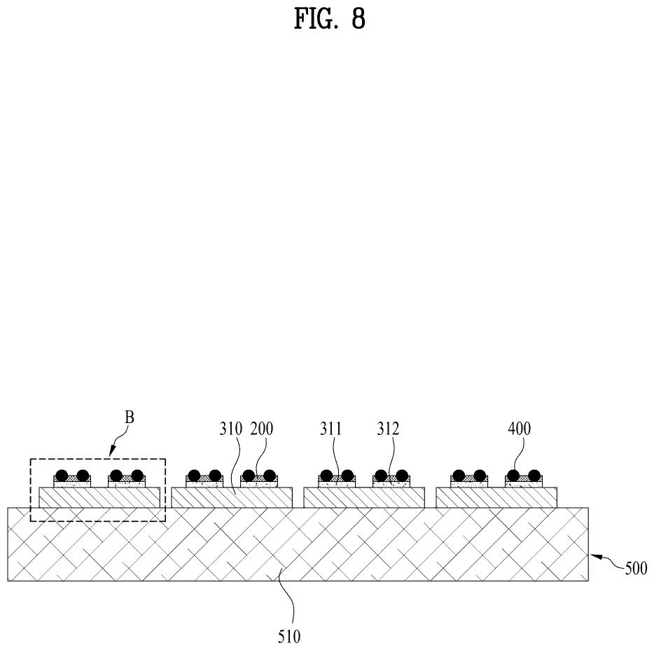

FIG. 7 is a flowchart showing a method of manufacturing the display device using the semiconductor light emitting elements according to one embodiment of the present disclosure. In addition, FIGS. 8 to 21 are schematic cross-sectional views showing each operation in the method of manufacturing the display device using the semiconductor light emitting elements according to one embodiment of the present disclosure.

Hereinafter, the method of manufacturing the display device using the semiconductor light emitting elements according to one embodiment of the present disclosure will be described in detail with reference to FIGS. 7 and 8 to 21.

First, a pattern of a conductive nanoparticle (particle) adhesive (adhesive parts) may be coated on a chip on wafer (COW) (S10).

Formation of the adhesive parts (conductive adhesive parts 200) including the conductive nanoparticles may be achieved through a detailed process (S20).

That is, the detailed process (S20) of forming the conductive adhesive parts CNPs may utilize any one of a photolithography process (S21), gravure printing (S22), gravure offset printing (S23), and inkjet printing (S24).

Thereafter, conductive balls 400 may be transferred onto the conductive adhesive parts 200 (S30). As such, when the conductive balls 400 are transferred onto the conductive adhesive parts 200, a state as shown in FIG. 8 may be achieved.

FIG. 8 illustrates the state in which the conductive adhesive parts 200 and the conductive balls 400 are formed on a growth substrate 500 using the above process (20).

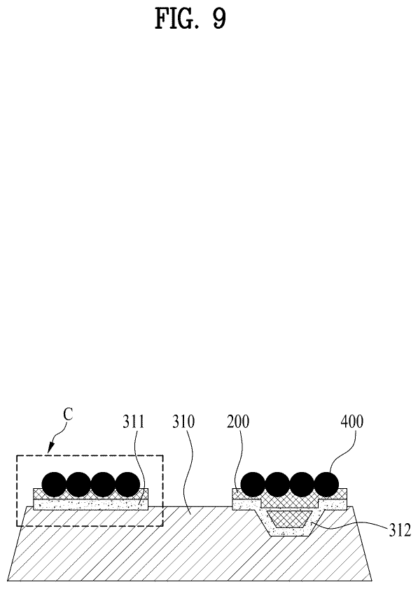

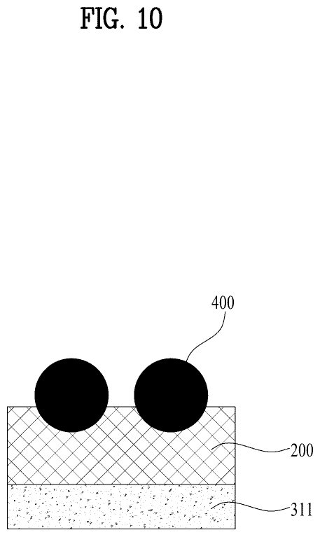

FIG. 9 is an enlarged view of portion B of FIG. 8, showing that the conductive adhesive part 200 is formed on each of the first-type electrode 311 and the second-type electrode 312 of the light emitting element 300 to have the same area (width) as the first-type electrode 311 or the second-type electrode 312. FIG. 10 is an enlarged view of portion C of FIG. 9.

FIG. 9 shows a state in which the conductive balls 400 are transferred with the same width as the conductive adhesive part 200. That is, an area in which the conductive balls 400 are transferred may be substantially the same as an area in which the conductive adhesive part 200 is formed.

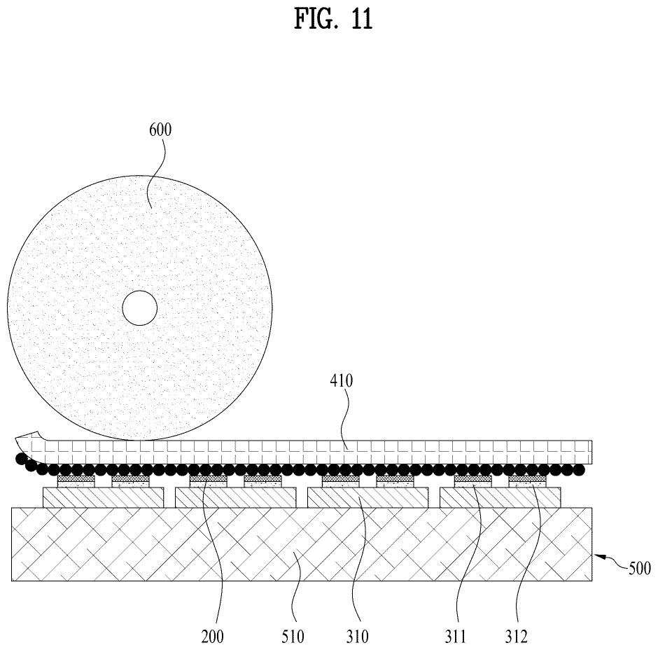

FIG. 11 shows a process of transferring the conductive balls 400 onto the conductive adhesive parts 200.

First, a monolayer film 410 to which the conductive balls 400 are attached may be placed in a state in which the conductive adhesive parts 200 are patterned on the first-type electrodes 311 and the second-type electrodes 312 of light emitting elements 310, and the conductive balls 400 may be transferred onto the conductive adhesive parts 200 using a roller 600 on the monolayer film 410.

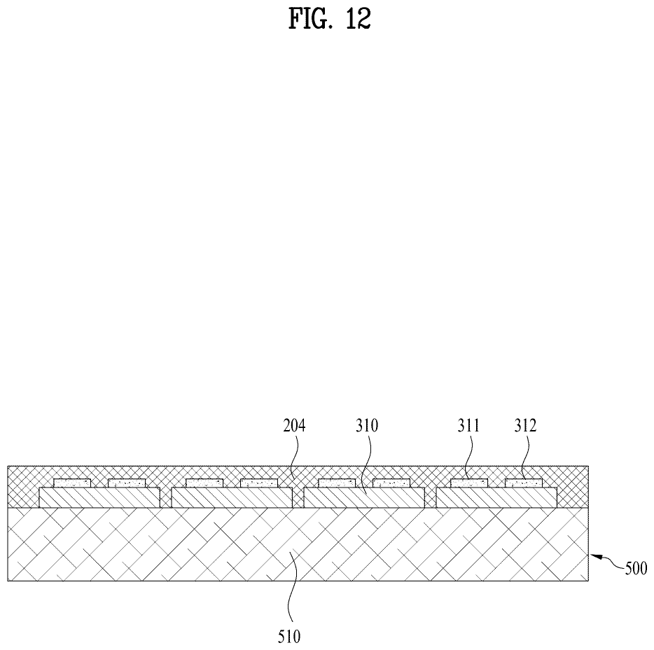

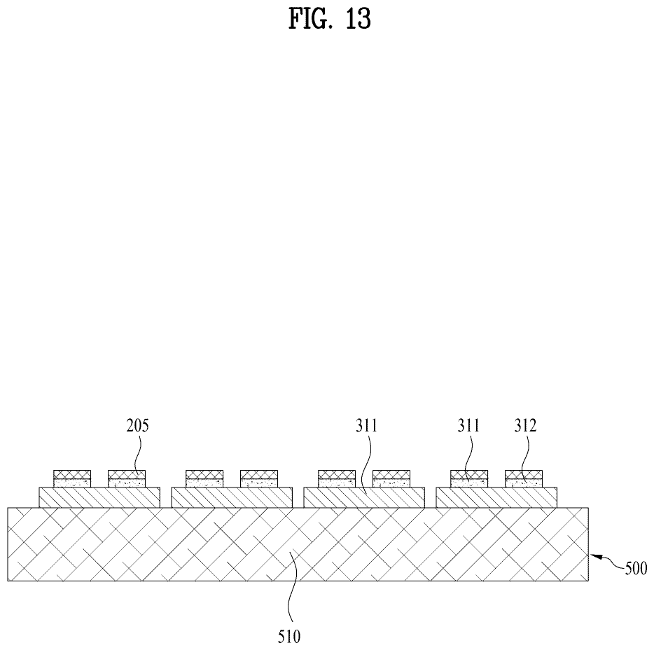

FIGS. 12 and 13 exemplarily show a process of forming a conductive adhesive layer 205 on the growth substrate 500.

First, as shown in FIG. 12, a conductive adhesive layer 204 may be formed to cover all the first-type electrodes 311 and the second-type electrodes 312 in a state in which the light emitting elements 310 are grown on a substrate 510 of the growth substrate 500 to be separated from each other. That is, the conductive adhesive layer 204 that covers the entire upper surface of the substrate 510 may be formed.

Thereafter, the conductive adhesive layer 204 may be patterned so that the conductive adhesive layer 205 is located only on the first-type electrodes 311 and the second-type electrodes 312.

Next, as described above, the conductive balls 400 may be transferred onto the conductive adhesive layer 205.

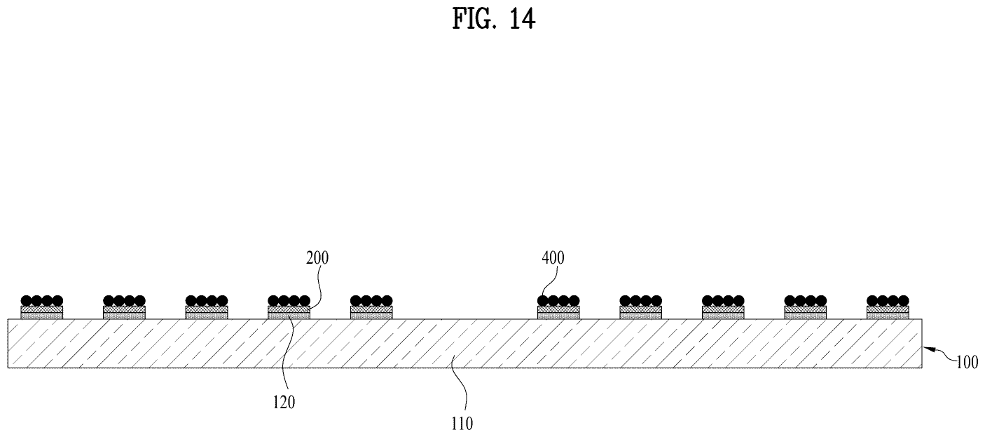

FIG. 14 exemplarily shows a state in which the conductive adhesive layer 200 is formed on the wiring substrate 100. That is, instead of transferring the conductive balls 400 onto the first-type electrodes 311 and the second-type electrodes 312 of the light emitting elements 310 on the growth substrate 100, the conductive adhesive layer 200 may be formed on the wiring electrodes 120 of the wiring substrate 100 and the conductive balls 400 may be transferred thereonto.

As described above, if the conductive balls 400 are not transferred onto the wiring substrate 100, the conductive adhesive layer 200 may be formed on the wring electrodes 120.

For example, it may be determined whether the bonding margin is less than or equal to a designated area (S40), and the pattern of the conductive adhesive layer 20 may be additionally formed if the bonding margin is greater than the designated area. For example, if the bonding margin is less than or equal to 6 inches, the transfer process of the light emitting elements 310 may be performed (S50), but if not, that is, if the bonding margin is greater than 6 inches, the pattern of the conductive adhesive layer 200 may be additionally formed. For example, if the bonding margin is greater than 6 inches, the conductive adhesive layer 200 may be additionally formed on the wiring electrodes 120.

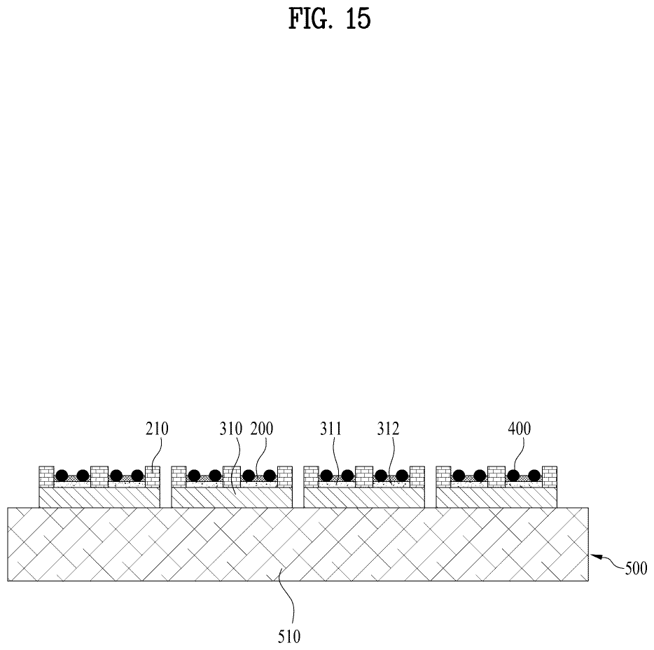

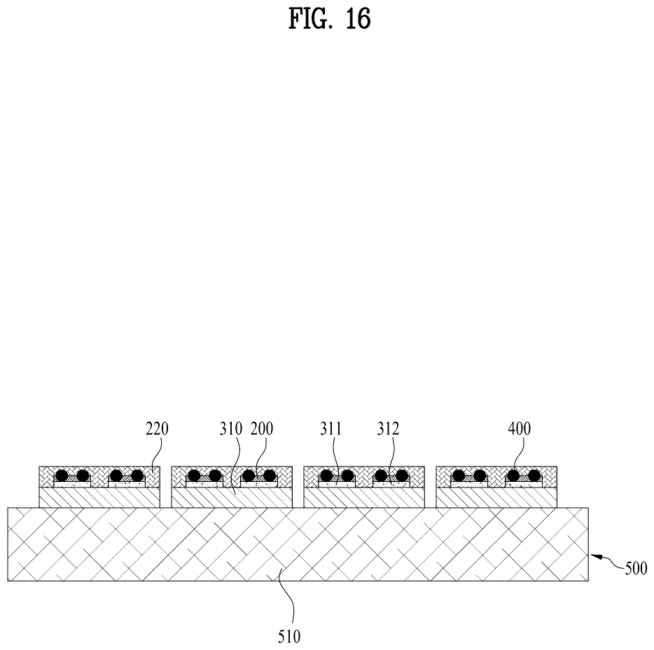

FIGS. 15 and 16 exemplarily show a process of forming a pattern of the cap layer 210 after transferring the conductive balls 400 onto the growth substrate 500.

As described above, the cap layer 210 may be located at the connection portions between the light emitting element 310 and the wiring electrodes 120. The cap layer 210 may act as a bonding fixing material (adhesive part) that fixes the connection state between the light emitting element 310 and the wiring electrodes 120.

As shown in FIG. 15, a cap layer 220 may be formed to surround the conductive adhesive layer 200 and the conductive balls 400 located on the first-type electrode 311 and the second-type electrode 312 of the light emitting element 310.

Thereafter, as shown in FIG. 16, the cap layer 220 may be patterned to so that the conductive adhesive layer 200 and the conductive balls 400 are exposed.

This cap layer 210 may be formed to surround the connection portion between the first-type electrode 311 and the wiring electrode 120 and the connection portion between the second-type electrode 312 and the wiring electrode 120.

Thereafter, the transfer process of the light emitting elements 310 may be performed. This transfer process of the light emitting elements 310 may be varied depending on whether a donor is used.

That is, it may be determined that the donor is used (S50), and if the donor is not used, a donor-free wiring substrate transfer process (S61) may be performed. For example, the transfer process of the light emitting elements 310 from the growth substrate 500 directly to the wiring substrate 100 may be performed without using separate donor substrates.

On the other hand, if separate donor substrates are used, a primary donor split transfer process (S60) may be performed first.

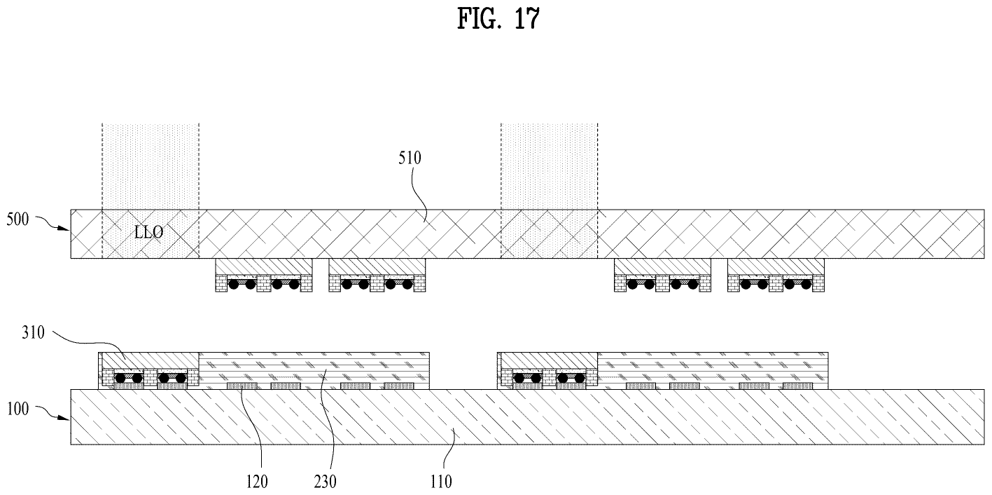

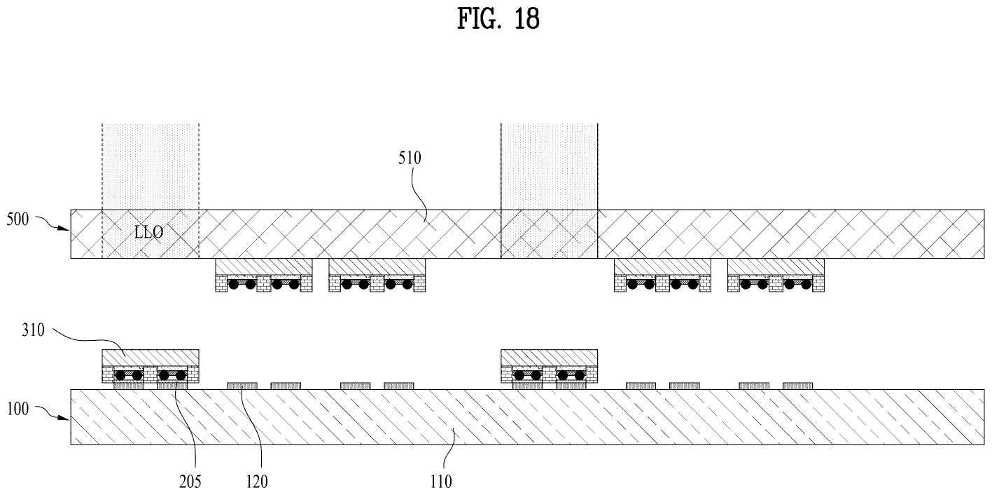

FIGS. 17 and 18 show examples of performing the donor-free wiring substrate transfer process without using a donor.

First, FIG. 17 illustrates, as an example of the donor-free wiring substrate transfer process, a transfer process using a pattern of an adhesive 230, such as a non-conductive paste (NCP).

FIG. 17 illustrates a process of preparing the wiring substrate 100 including the substrate 110 provided with the electrode pads 120 formed thereon, locating light emitting elements (for example, first light emitting elements 310) arranged on the growth substrate 500 at the positions of the wiring electrodes 120 above the wiring substrate 100, and then transferring the light emitting elements 310 onto the wiring electrodes 120.

By this process, the pattern of the adhesive 230, such as the non-conductive paste (NCP), may be located on the electrode pads 120, and the light emitting element 310 may be transferred onto the pattern of the adhesive 230.

At this time, the light emitting element 310 may be separated from the growth substrate 500 and transferred to the wiring electrodes 120 by a laser lift-off (LLO) method.

That is, the process of transferring the light emitting element 310 onto the wiring electrodes 120 of the wiring substrate 100 may include irradiating the light emitting element 310 with a laser from the growth substrate 500 side.

When the light emitting element 310 is irradiated with the laser from the growth substrate 500 side, the substrate 510 of the growth substrate 500 and the light emitting element 310 may be separated from each other at the interface therebetween.

The light emitting element 310 separated from the substrate 510 of the growth substrate 500 may be electrically connected to the wiring electrodes 120 by penetrating the pattern of the adhesive 230.

FIG. 18 illustrates, as another example of the donor-free wiring substrate transfer process, a transfer process using conductive nanoparticle pattern as an adhesive part on the wiring substrate 100.

FIG. 18 illustrates a process of preparing the wiring substrate 100 including the substrate 110 provided with the electrode pads 120 formed thereon, locating light emitting elements (for example, first light emitting elements 310) arranged on the growth substrate 500 at the positions of the electrode pads 120 above the wiring substrate 100, and then transferring the light emitting elements 310 onto the wiring electrodes 120.

By this process, the adhesive parts 205 including conductive nanoparticles may be located on the first-type electrode 311 (see FIG. 15) and the second-type electrode 312 of the light emitting element 310. The light emitting element 310 may be transferred so that the adhesive parts 205 and the conductive balls 400 are located on the wiring electrodes 120.

At this time, the light emitting element 310 may be separated from the growth substrate 500 and transferred to the wiring pads 120 by the laser lift-off (LLO) method.

That is, the process of transferring the light emitting element 310 onto the wiring electrodes 120 of the wiring substrate 100 may include irradiating the light emitting element 310 with a laser from the growth substrate 500 side.

When the light emitting element 310 is irradiated with the laser from the growth substrate 500 side, the substrate 510 of the growth substrate 500 and the light emitting element 310 may be separated from each other at the interface therebetween.

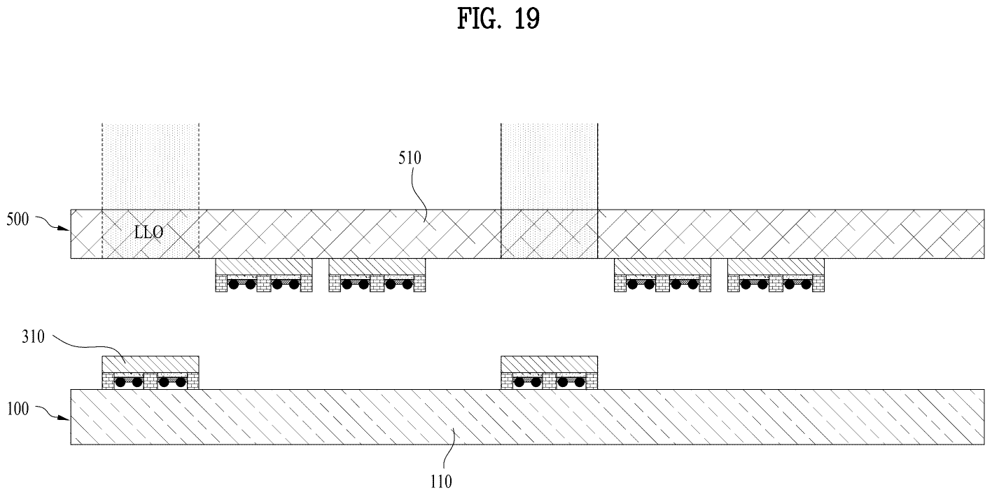

FIGS. 19 to 21 show examples of a transfer process using donor substrates.

As such, when using donor substrates, since the bonding direction of the light emitting element 310 is changed, and two donor transfer processes may be required.

That is, referring to FIG. 7, the transfer process using the donor substrates may include the primary donor transfer process (S60) and a secondary donor transfer process (S70).

In addition, FIG. 19 illustrates a process of preparing a donor substrate 600, locating light emitting elements (for example, first light emitting elements 310) arranged on the growth substrate 500 above the donor substrate 600, and then transferring the light emitting elements 310 onto the donor substrate 600.

At this time, the light emitting element 310 may be separated from the growth substrate 500 and transferred onto the donor substrate 500 by the laser lift-off (LLO) method.

As described above, the process of transferring the light emitting elements 310 onto the donor substrate 600 may include irradiating the light emitting elements 310 with a laser from the growth substrate 500 side (laser lift-off (LLO)).

This transfer process of the light emitting elements 310 may be performed sequentially for each of colored light emitting elements 310, 320, and 330.

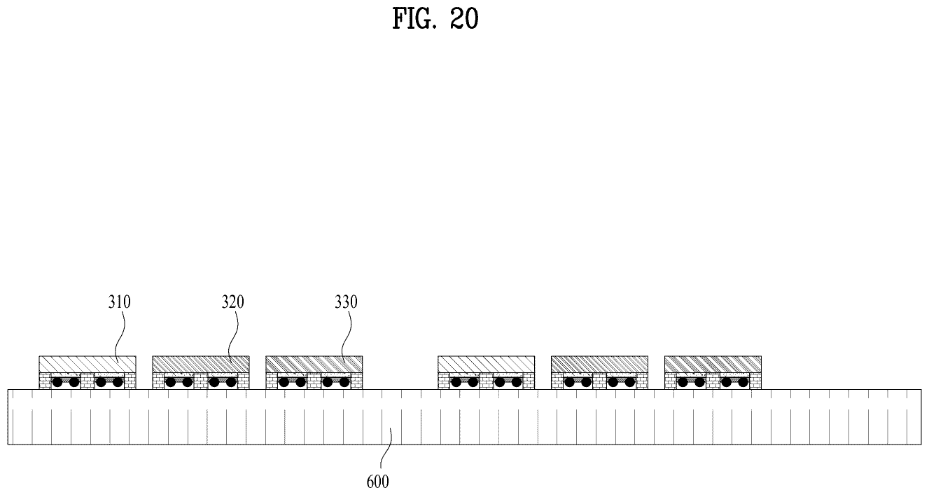

FIG. 20 shows a state in which the light emitting elements 310, 320, and 330 are primarily transferred onto the (first) donor substrate 600 in this manner. At this time, the light emitting elements 310, 320, and 330 may be transferred with the conductive balls 400 facing the first donor substrate 600.

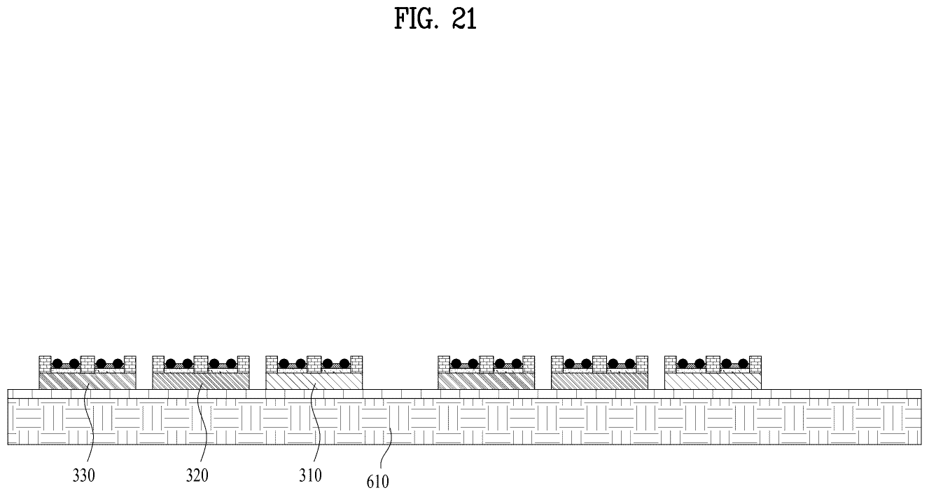

Thereafter, when the secondary donor transfer process (S70) is performed, as shown in FIG. 21, a state in which the light emitting elements 310, 320, and 330 are transferred onto a second donor substrate 610 may be achieved.

Referring to FIG. 21, the light emitting elements 310, 320, and 330 may be transferred onto the second donor substrate 610. At this time, unlike FIG. 20, the light emitting elements 310, 320, and 330 may be transferred with the conductive balls 400 facing upward, i.e., the upper and lower positions of the light emitting elements 310, 320, and 330 may be reversed.

Thereafter, the light emitting elements 310, 320, and 330 disposed on the secondary donor substrate 610 may be transferred onto the wiring substrate 100.

In this process, the adhesive parts 200 may be coated on the wiring electrodes 120 (S80), and the first-type electrode 311 and the second-type electrode 312 of the light emitting element 310 may be electrically connected to the wiring electrodes 120 by the adhesive parts 200 (S90).

By this process, bonding between the first-type electrode 311 and the second-type electrode 312 of the light emitting element 310 and the wiring electrodes 120 may be completed.

Thereafter, a paste curing process, etc. may be performed as needed.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are exemplary and not intended to limit the technical idea of the present disclosure, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

### Industrial Applicability

According to the present disclosure, a display device using semiconductor light emitting elements, such as micro-LEDs, may be provided.

1. A display device using semiconductor light emitting elements comprising:
a wiring substrate;
first electrodes configured to define unit subpixel areas and arranged on the wiring substrate;
light emitting elements having first-type electrodes disposed on the first electrodes;
a plurality of conductive balls configured to electrically connect the first-type electrodes of the light emitting elements to the first electrodes; and
conductive adhesives parts located on the conductive balls to fix the conductive balls to at least one of the first electrodes or the first-type electrodes,
wherein the conductive adhesive parts comprise:
first adhesive parts located on the first-type electrodes; and
second adhesive parts located on the first electrode.

2. The display device of claim 1, wherein the conductive adhesive parts comprise conductive nanoparticles.

3. The display device of claim 1, wherein the conductive adhesive parts comprise a photoresist or a paste.

4. The display device of claim 1, wherein the conductive adhesive parts comprise a non-conductive paste comprising conductive nanoparticles.

5. The display device of claim 1, wherein the conductive adhesive parts are locally located on the first-type electrodes.

6. The display device of claim 2, wherein the light emitting elements are electrically connected to the first electrodes by the conductive balls and the conductive nanoparticles.

7. The display device of claim 1, wherein the conductive adhesive parts have the same width as at least one of the first electrodes or the first-type electrodes.

8. (canceled)

9. The display device of claim 1, wherein the first adhesive parts and the second adhesive parts are in contact with each other.

10. The display device of claim 1, wherein the first adhesive parts and the second parts are spaced apart from each other, and are electrically connected by the conductive balls.

11. A display device using semiconductor light emitting elements comprising:
a wiring substrate;
first electrodes configured to define unit subpixel areas and arranged on the wiring substrate;
light emitting elements having first-type electrodes disposed on the first electrodes;
a plurality of conductive balls configured to electrically connect the first-type electrodes of the light emitting elements to the first electrodes; and
conductive adhesive parts located on the conductive balls to fix the conductive balls to at least one of the first electrodes or the first-type electrodes,
wherein the conductive adhesive parts comprise conductive nanoparticles.
wherein the conductive adhesive parts comprise:
first adhesive parts located on the first-type electrodes; and
second adhesive parts located on the first electrodes.

12. The display device of claim 11, wherein the adhesive parts comprise a photoresist or a paste.

13. The display device of claim 11, wherein the adhesive parts are locally located on the first-type electrodes.

14. The display device of claim 11, wherein the light emitting elements are electrically connected to the first electrodes by the conductive balls and the conductive nanoparticles.

15. (canceled)

16. The display device of claim 11, wherein the first adhesive parts and the second adhesive parts are in contact with each other.

17. The display device of claim 11, wherein the first adhesive parts and the second parts are spaced apart from each other, and are electrically connected by the conductive balls.

18. The display device of claim 11, wherein the adhesive parts have the same width as at least one of the first electrodes or the first-type electrodes.
